(19) United States
(12) Patent Application Publication
(10) Pub. No.: US 2023/0051143 A1
(43) Pub. Date: Feb. 16, 2023

(54) HIGH-VOLTAGE TRIGGERED PULSECLOSER WITH ADAPTIVE CIRCUIT TESTING

(71) Applicant: S&C Electric Company, Chicago, IL (US)

(72) Inventors: Edgar Casale, Lewis Center, OH (US); Michael G. Ennis, Evanston, IL (US); Alejandro Montenegro, Chicago, IL (US); Yoav Sharon, Evanston, IL (US); William Yadusky, Franklin, WI (US)

(73) Assignee: S&C Electric Company, Chicago, IL (US)

(21) Appl. No.: 17/853,974

(22) Filed: Jun. 30, 2022

Related U.S. Application Data
(60) Provisional application No. 63/232,313, filed on Aug. 12, 2021.

(51) Int. Cl. H03K 3/537; H01T 2/02

(52) U.S. Cl. CPC H03K 3/537; H01T 2/02

(57) ABSTRACT

A system and method for maintaining electrical stability of a high-voltage transmission power system in response to a fault. The method includes detecting the fault, opening a switch to clear the fault, performing a first pulse test for a predetermined duration of time to determine if the fault is still present, preventing a reclosing operation from occurring if the pulse test indicates that the fault is still present, and allowing the reclosing operation to occur if the first pulse test indicates that the fault is not present. One or more subsequent pulse tests can be performed if the first pulse test is inclusive about the persistence of the fault, where the reclosing operation is prevented from occurring if the pulse tests indicate that the fault is still present and the reclosing operation is allowed if the pulse tests indicate that the fault is no longer present.

### CROSS-REFERENCE TO RELATED APPLICATION

This application claims the benefit of priority from the U.S. Provisional Application No. 63/232,313, filed on Aug. 12, 2021, the disclosure of which is hereby expressly incorporated herein by reference for all purposes.

### BACKGROUND

### Field

This disclosure relates generally to a system and method for maintaining electrical stability of a power system in response to a fault using pulse-testing using a triggered vacuum gap (TVG) device.

### Discussion of the Related Art

An electric power network, often referred to as an electrical grid, typically includes power generation plants each having power generators, such as gas turbines, nuclear reactors, coal-fired generators, hydro-electric dams, etc. The power plants provide power at a variety of medium voltages that are then stepped up by transformers to a high voltage AC signal to be connected to high voltage transmission lines that deliver electrical power to substations typically located within a community, where the voltage is stepped down by transformers to a medium voltage for distribution. The substations provide the medium voltage power to three-phase feeders including three single-phase feeder lines that provide medium voltage to various distribution transformers and lateral line connections. three-phase and single-phase lateral lines are tapped off of the feeder that provide the medium voltage to various distribution transformers, where the voltage is stepped down to a low voltage and is provided to loads, such as homes, businesses, etc. Electric power networks of the type referred to above typically include switching devices, breakers, reclosers, interrupters, etc. that control the flow of power throughout the network.

Periodically, faults occur in the electric power network as a result of various things, such as animals touching the lines, lightning strikes, tree branches falling on the lines, vehicle collisions with utility poles, etc. Faults may create a short-circuit that increases the load on the network, which may cause the current flow from the substation to significantly increase, for example, many times above the normal current, along the fault path. This amount of current causes the electrical lines to significantly heat up and possibly melt, and also could cause mechanical damage to various components in the substation and in the network. Many times the fault will be a temporary or intermittent fault as opposed to a permanent or bolted fault, where the thing that caused the fault is removed a short time after the fault occurs, for example, a lightning strike, where the distribution network will almost immediately begin operating normally.

Fast fault-clearing is widely accepted as one of the most effective techniques for improving or maintaining transient stability in utility grids while simultaneously limiting the let-through current that can damage equipment. After the fault has been initially cleared, reclosing as soon as possible helps maintain or restore network stability by returning the circuits to their pre-fault configuration. Traditional reclosing is most effective only if the fault has been cleared, otherwise the full fault current is re-applied every time a hard-reclose is attempted. Reclosing into a persistent fault may cause or exacerbate network instability, especially in high-voltage networks where the available fault current may be tens of thousands of Amperes. This high available fault current may also cause immediate or latent damage to power system equipment. The characteristically low network impedance of high-voltage networks also allows steep rates of rise of the available fault current, which means the fault current will reach potentially damaging levels very quickly unless it is interrupted very quickly.

In order to provide fault clearing in this manner, fault interrupters, such as reclosers, are often provided that have a switch to allow or prevent power flow downstream of the recloser. These reclosers detect the current and voltage on the feeder to monitor current flow and look for problems with the network circuit, such as detecting a fault. If fault current is detected the recloser is opened in response thereto, and then after a short delay is closed in a process for determining whether the fault is still present. If fault current flows when the recloser is closed, it is immediately opened. If the fault current is detected again or two more times during subsequent opening and closing operations, then the recloser remains open, where the time between tests may increase after each test.

Recloser type devices are known that use pulse testing technologies where the closing and then opening of switch contacts is performed in a pulsed manner, and where the pulses are typically less than one-half of a current cycle so that the full fault current is not applied to the network while the recloser is testing to determine if the fault is still present. Pulse closing technologies have been successful in significantly reducing fault current stresses on network equipment during recloser testing. However, the switching devices required to generate these short pulse durations are relatively complicated and expensive. For example, vacuum interrupters employed to generate these pulses often use two magnetic actuators, one to close the contacts and one to quickly open the contacts using the moving mass of the opening actuator to reverse the direction of the closing actuator, well understood by those skilled in the art.

It has been proposed to employ TVG devices as the switching mechanism for use in pulse testing that does not require moving parts. A typical TVG device includes two stationary main electrodes positioned within a vacuum chamber, where a main vacuum gap is defined between the electrodes. The TVG device also includes a triggering element, such as a triggering electrode, where a triggering vacuum gap is provided between the triggering electrode and the corresponding main electrode. The triggering gap is designed to have a much smaller gap length than the main vacuum gap so that its breakdown voltage is much lower than the breakdown voltage of the main gap. The triggering gap can be bridged by an insulator, such as ceramic, in order to make its breakdown voltage even lower. When a sufficiently high triggering voltage impulse is applied to the main electrode and the triggering electrode across the triggering gap, the triggering gap breaks down. This breakdown across the triggering gap creates a plasma cloud that propagates in a fraction of microsecond into the main gap and causes breakdown of the main gap, where this state of the TVG device represents a closed switch. Once the current flow in the TVG device begins it does not stop until the AC current signal on the electrodes cycles through a zero crossing point. When this occurs, the plasma is extinguished by the vacuum and the arc dissipates. Because the plasma can be ignited in the vacuum chamber in this manner, the timing of when the device conducts can be tightly controlled, i.e., on the order of micro-seconds. Further, because the electrodes don't move, there is not a requirement for an accurate mechanical actuation.

Since TVG devices are easily and accurately triggerable even at a relatively low voltage across the main vacuum gap of just a few kV, the delays associated with generating the plasma cloud that effectively closes the switch can be tightly controlled to within a few microseconds of the desired instant of pulse testing. Once the triggered gap is conducting current, it is also able to interrupt even a high current at the first line-frequency zero-crossing, and then to have a high withstand voltage across the main electrodes immediately after current interruption. These are powerful features, but those features have generally only been used in pulse power applications and not in electric power systems for synchronized closing applications. More specifically, TVG devices have an excellent ability to interrupt high-frequency currents as well as line-frequency currents at their high-frequency current zero-crossings. This is important because high-frequency currents are created by discharging and charging stray capacitances and inductances during any switching operation in a power system. Such transient high-frequency currents are usually attenuated very quickly and most often they are not even noticed when closing is performed by mechanical switches. However, for TVG devices high-frequency current zero-crossings may have the undesirable effect of prematurely extinguishing the plasma arc during a pulse test. There is a high probability that a TVG device will interrupt current in one of several high frequency current zeroes that occur in the first 100 microseconds after current was pulse-generated in the TVG device. Current interruption is a statistical event that depends on physical processes of vacuum arc, di/dt, contact material, etc. If the high-frequency current zero-crossing extinguishes the plasma arc, then the TVG device must be retriggered, however the transient high-frequency currents will likely occur again and create current zero-crossings in the TVG current, once again interrupting the TVG current.

If it were possible to sustain the TVG device plasma arc and current conduction through high-frequency current zeroes in a controlled manner, then the TVG device would not stop conduction at all. Several hundred microseconds after triggering, the line-frequency current in the TVG device becomes sufficiently high, and high frequency currents become sufficiently attenuated, that “premature” current zero-crossings are effectively eliminated. This means that closing by a TVG device will almost be successful in a distribution or transmission power system if the TVG device maintains conduction during in the first approximately 300 microseconds after triggered breakdown by riding through any high-frequency current zero-crossings during that period.

While various fault interruption devices and reclosing techniques based on mechanical switches exist for lower level distribution systems, they often do not scale to higher voltage transmission systems due to the mechanical stress resulting from those higher voltages and currents, which undesirably requires larger and more costly components. Additionally, the use of larger mechanical components may also pose synchronization issues or result in other problems due to the increased amount of time and energy required to activate such larger components. Accordingly, it is desirable to provide improved fault detection devices and reclosing schemes suitable for use with higher voltage transmission applications.

### SUMMARY

The following discussion discloses and describes a system and method for maintaining electrical stability of a high-voltage transmission power system or medium voltage distribution system in response to a fault. The method includes detecting the fault, opening a switch to clear the fault, performing a pulse test for a predetermined duration of time to determine if the fault is still present, preventing a reclosing operation from occurring if the pulse test indicates that the fault is still present, and allowing the reclosing operation to occur if the first pulse test indicates that the fault not present. Subsequent pulse tests can be performed if the first pulse test is inconclusive about the persistence of the fault, where the reclosing operation is prevented from occurring if the pulse tests indicate that the fault is still present and the reclosing operation is allowed to occur if the pulse tests indicate that the fault is no longer present.

Additional features of the disclosure will become apparent from the following description and appended claims, taken in conjunction with the accompanying drawings.

### BRIEF DESCRIPTION OF THE DRAWINGS

FIG. 1 is a block diagram of a pulse-closing system for a high voltage transmission power network;

FIG. 2 is a cross-sectional type view of a TVG device that can be used in the pulse-closing device shown in FIG. 1; and

FIG. 3 is a graph with time on the horizontal axis and voltage on the vertical axis showing sensitivity to pulse-testing and hard reclosing after one-cycle of fault clearing.

### DETAILED DESCRIPTION OF THE EMBODIMENTS

The following discussion of the embodiments of the disclosure directed to a system and method for maintaining electrical stability of a high-voltage transmission power system in response to a fault using pulse testing is merely exemplary in nature and is in no way intended to limit the disclosure or its applications or uses.

It is critical that power transmission be stable by balancing between generation and consumption of power on an instantaneous basis, where this is typically provided by making sure power generation is kept on-line. When a fault event occurs in a power transmission network, a reclose operation in response thereto may cause destabilization of the network, which would subsequently cause more harm than good, i.e., the attempt to restore power causes a broader loss of power. The present disclosure determines how and when to perform a reclose operation after a fault has been cleared to ensure that the network does not become unstable. Various parameters, such as voltage angles in the network, are calculated and/or observed that determine whether the network is returning to stability or becoming unstable after a fault is cleared to determine if a reclosing operation can be performed. If the network is tending toward stability, then pulse-tests are performed to determine if the fault is still present before the reclosing operation is performed.

As will be discussed, the present disclosure proposes a system and method for rapid and repeated tests for the persistence of a fault without performing hard reclosing, where the system employs a switch having a TVG device. As soon as the system has detected and cleared the fault, the switch recloses using point-on-wave timing and other factors to optimize speed and network stability. The following discussion assumes that the “switch” consists of three separate poles (one for each phase in a three-phase system) whose operation is coordinated as a single three-pole switch. However, other embodiments allow independent single-pole operation, or separate timing for point-on-wave opening and closing of each pole in a three-phase implementation.

Once a fault is detected using one or more of the fast-fault-detection schemes, the controls issue an initial permissive to clear the suspected fault by actuating the switch that has been optimized for opening-speed. While the initial permissive-to-clear is being processed in the controls, double-checks are performed against parallel computations, such as DFT, spectral analysis and V-versus-I (impedance) measurements to ensure that a suspected fault was not erroneously detected. In addition, the type of fault, i.e., line-to-ground (LG), line-to-line (LL), line-to-line-to-ground (LLG), line-to-line-to-line (LLL) or line-to-line-to-line-to-ground (LLLG), is identified where possible to help identify the optimal scheme for subsequent triggered pulse testing to improve both accuracy and speed of determining when a fault of any type has cleared.

In one embodiment, the triggering electrode of the TVG device is located only in the stationary contact of the switch, here presumed to be a vacuum interrupter. This permits triggered pulse testing only once in a line-frequency cycle, and specifically in the positive voltage half-cycle, near the negative-going voltage zero-crossing. In another embodiment, triggering electrodes are located both in the stationary contact and in the moving-contact end of the vacuum bottle. This permits triggered pulse testing twice during a line-frequency cycle. If the parallel computations indicate that the fault detection may be a false-positive leading to a nuisance trip, then the initial permissive may be withdrawn within the timeframe that switch contacts can be actuated, and transition into the triggered pulse-closing mode is inhibited.

If the slower double-check computations are incomplete, inconclusive, or even contradictory to the initial fault detection, then the permissive is either reinforced or withdrawn according to a pre-configured selection to avoid false positives or false negatives, depending on which is considered worse for the application. Timing may also be configured for a specific application. Such timing is a system-level double-check of the initial permissive to actuate the switch to clear the fault.

If a true fault is detected, and switches have opened to clear the fault, then the device controls transition into a triggered pulse-closing mode to determine when the fault has cleared and consequently the earliest time the switches may be reclosed. To do this, the triggering electrodes in the switches are periodically energized at a precise point-on-wave to ignite a plasma arc across the open contact gaps. The resulting current, which is of a much lower magnitude than the available fault current, and of only a few milliseconds duration, is measured and analyzed to determine if the fault is still present or not on any of the phases. If the fault is determined to have cleared, then an initial permissive is issued to reclose the contacts. If the fault has not cleared, then no permissive is issued and the device waits for the next point-on-wave opportunity to trigger the pulse test.

Interfaces with external current and voltage monitors, as well as with external control and status signaling all of which may be available in substations, are accounted for. However, a communications infrastructure with sufficient bandwidth and data rates required to interface the local, external measurement and control systems to the triggered pulse testing may not exist at all such substations. Consequently, for the purposes of this discussion it is assumed that voltage and current sensing, and the control/status signals, are performed internally to the triggered pulse testing, although such sensing and signaling may be provided by external devices.

In other embodiments, the controls may wait a predetermined amount of time before triggered pulse-closing at a fixed periodic interval; the controls may wait a configured amount of time before triggered pulse-closing at a variable periodic interval; the controls may cease triggered pulse-closing if the fault is determined not to have cleared within a specified amount of time, such as within the critical reclosing interval; the controls may cease triggered pulse-closing if the fault is determined not to have cleared after a specified number of triggered pulse-closings; the controls may receive instructions from an external control system to start or stop triggered pulse-closing; the controls may be configured according to conventional TCC curves or other application-specific timing considerations; the controls may be configured not to perform triggered pulse-closing or to reclose at all; the controls may adjust the pulse-test interval based on the magnitude of the measured fault current, and/or the controls of one triggered pulse-closer may coordinate with other triggered pulse-closers to interleave their respective pulse-closing activities to gain additional situational awareness, such as fault-locating or integration with distance and differential relaying schemes.

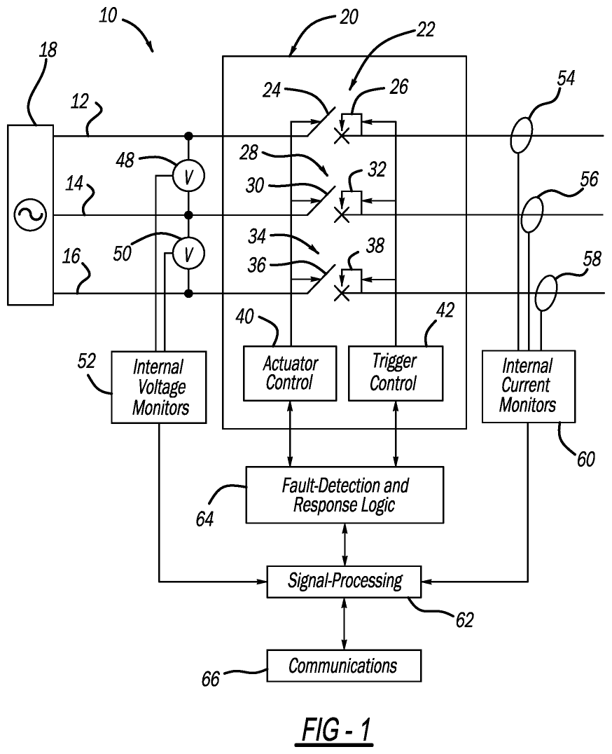

FIG. 1 is a block diagram of a pulse-closing system 10 illustrating the components that can be used for maintaining electrical stability of a high-voltage transmission or medium voltage distribution power system in response to a fault as discussed above. The system 10 includes three high-voltage transmission lines 12, 14 and 16 one for each phase A, B and C that receive high voltage power from a power generator 18, such as a turbine. A pulse-closing device 20 is coupled to the lines 12, 14 and 16 and includes a switch assembly 22 having a reclosing switch 24, such as a vacuum interrupter, and a pulse testing TVG device 26 in the line 12, a switch assembly 28 having a reclosing switch 30 and a pulse testing TVG device 32 in the line 14, and a switch assembly 34 having a reclosing switch 36 and a pulse testing TVG device 38 in the line 16. The pulse-closing device 20 also includes an actuator control 40 that opens and closes the switches 24, 30 and 36 during the fault clearing and reclosing operation and a trigger control 42 that generates the plasma arc in the TVG devices 26, 32 and 38.

A voltage sensor 48 is coupled to the lines 12 and 14 at the line-side of the device 20 and a voltage sensor 50 is coupled to the lines 14 and 16 at the line-side of the device 20 to provide voltage measurements on the lines 12, 14 and 16. A voltage monitor 52 receives voltage measurements from the sensors 48 and 50. A current sensor 54 provides current measurements on the line 12, a current sensor 56 provides current measurements on the line 14 and a current sensor 58 provides current measurements on the line 16. A current monitor 60 receives the current measurements from the sensors 54, 56 and 58. This configuration of voltage monitoring uses line-to-line voltage measurements from the sensors 48 and 50. In an alternate embodiment, the voltage measurements may be line-to-ground measurements requiring three voltage sensors. A signal processor 62 receives voltage and current signals from the monitors 52 and 60, processes the signals and provides the processed signals to a fault detection and response logic controller 64 that commands the actuator control 40 and the trigger control 42 to control the switches 24, 30 and 36 and the TVG devices 26, 32 and 38 consistent with the discussion herein. The signal processor 62 is in communications with a communications device 66 to receive voltage and current signals, status signals, etc. from other components in the network.

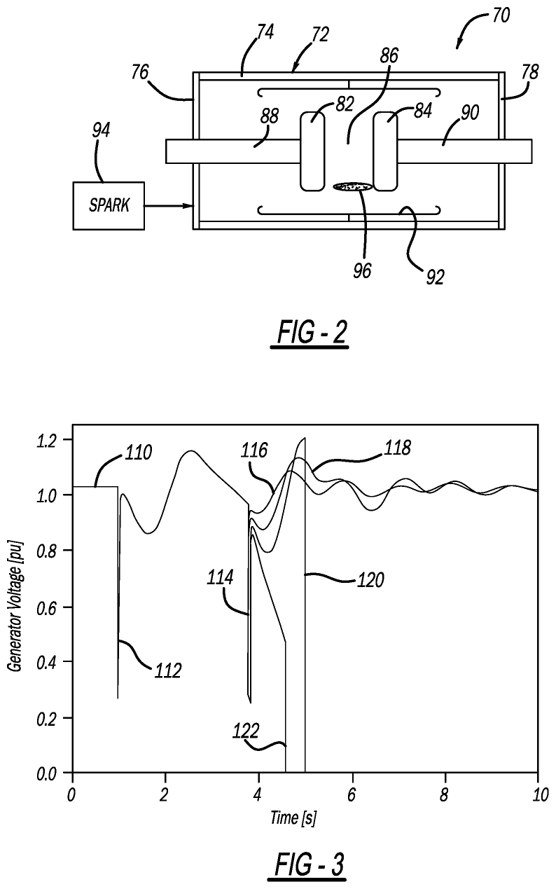

The TVG devices 26, 32 and 38 can be any TVG device suitable for the purposes discussed herein. FIG. 2 is a cross-sectional type view of an exemplary embodiment of an electrically-triggered TVG device 70 to show one representative example. The TVG device 70 includes a vacuum enclosure 72 having a cylindrical insulator 74 and conductive end plates 76 and 78. In exemplary embodiments, the vacuum enclosure 72 is sealed at vacuum pressure of at least 10⁻⁶ mbar and less than 10⁻³ mbar. The TVG device 70 also includes a pair of opposing conductive electrodes 82 and 84 defining a trigger gap 86 therebetween. The electrode 82 is connected to a stem 88 that extends through a sealed hole in the plate 76 and the electrode 84 is connected to a stem 90 that extends through a sealed hole in the plate 78, where the stems 88 and 90 provide connection for the device 70 to other switching elements. The internal surface of the insulator 74 is protected from conductive deposits by a cylindrical metallic vapor shield 92.

A pulse-triggering circuit 94 produces a sufficiently high-voltage/low-current pulse across the trigger gap 86 to initiate the plasma arc, which is then sustained for several hundred microseconds thereafter by a lower-voltage/higher-current pulse. In exemplary embodiments, the duration of the initial higher-voltage/lower-current pulse is a few microseconds and the duration of the lower-voltage/higher-current pulse is a few hundred microseconds. The geometry of the arrangement between the triggering electrode and its target surface is such that the initial pulse may be focused on a very small area on the electrode 82 so that the power density of the trigger pulse on the electrode surface is magnified and the electrical trigger energy transferred to the electrode leads to almost instantaneous vaporization of electrode material and transition of vapor into a dense plasma cloud 96 that expands towards the electrode 74 as a plasma plume and leads to electrical breakdown of the gap 106 and creation of a vacuum arc between the electrodes 82 and 84. Gap breakdown occurs based on the magnitude of the voltage differential between the electrodes 82 and 84 after the plasma cloud 96 is created. The electrode material may be chosen based on its triggering ability, i.e., its ablation ability under laser pulses, in conjunction with its vacuum arc interruption ability and dielectric strength in vacuum.

FIG. 3 is a graph with time on the horizontal axis and voltage on the vertical axis showing sensitivity to pulse-testing and hard reclosing after one-cycle of fault clearing for a permanent fault. Graph line 110 represents the voltage on one of the lines 12, 14 or 16. A fault is detected by the current and voltage measurements and the appropriate recloser switches 24, 30 or 36 is opened to clear the fault at time location 112. The voltage on the line begins to stabilize thereafter and a reclosing operation is scheduled to be performed at time location 114 to determine if the fault is still present, which it will be since the fault is permanent. Graph line 116 represents and 0.5-cycle pulse-test, graph line 118 represents and 1.5-cycle pulse-test, graph line 120 represents and 2.5-cycle hard reclose and re-open, and graph line 122 represents and 3.5-cycle hard reclose and re-open that could occur at the time location 114. Graph lines 120 and 122 show that for the traditional hard reclose, the fault is introduced back into the network causing the generator 18 to trip, which could lead to system stability. Fast pulse testing, either 0.5-cycle or 1.5-cycle shown by the graph lines 116 or 118, during the presence of a permanent fault maintains generation online, and therefore system stability indirectly, compared to hard-reclosing, either 2.5-cycle or 3.5-cycle conventional hard-reclosing followed by a re-open. In this case, the generator voltage collapses, indicating a trip-offline, for the hard-reclosing compared to the pulse testing. The graph shows that the fault is still present, and the reclose operation is not performed.

The present disclosure performs a first point-on-wave pulse test, for example, a ≤0.5 cycle pulse test, using the proper TVG device 26, 32 or 38 at the time location 114 so as to detect for the presence of the fault, but without placing significant fault current on the line. If the system is satisfied that the pulse test showed the fault is gone, then reclosing is allowed. Since pulse testing is generally benign to the network compared to hard reclosing, repetitive pulse tests may be applied, or limited by configuration, until either the fault is declared permanent and the device locks out, or the fault is determined to be no longer applied to the system whereupon the reclosing device receives a permissive to reclose. Therefore, multiple pulse tests of the same or longer duration can be performed if the first pulse test did not provide an adequate determination that the fault was or was not still present.

Since the pulse testing is low-energy, i.e., the amount of current allowed by the device to flow is substantially less than the available fault current if the fault is persistent, both the obvious and latent damage caused by let-through current in transformers and circuit breakers is avoided. Pulse testing should occur within the critical reclosing interval in order to create as small a disturbance on the network as possible. However, simulation results suggest that it may be possible to de-stabilize a transmission network by pulse testing too soon in the presence of a persistent fault.

The foregoing discussion discloses and describes merely exemplary embodiments of the present disclosure. One skilled in the art will readily recognize from such discussion and from the accompanying drawings and claims that various changes, modifications and variations can be made therein without departing from the spirit and scope of the disclosure as defined in the following claims.

What is claimed is:

1. A method for maintaining electrical stability of a power system in response to a fault, the method comprising:
detecting the fault;
opening a switch to clear the fault;
performing a first pulse test for a predetermined duration of time to determine if the fault is still present;
preventing a reclosing operation by the switch from occurring if the first pulse test indicates that the fault is still present; and
allowing the reclosing operation to occur if the first pulse test indicates that the fault is no longer present.

2. The method according to claim 1 wherein the first pulse test is performed by a triggered vacuum gap (TVG) device.

3. The method according to claim 1 wherein the predetermined duration of time is ≤0.5 cycles.

4. The method according to claim 1 further comprising performing subsequent pulse tests if the first pulse test is inclusive about the persistence of the fault, wherein preventing a reclosing operation from occurring includes preventing the reclosing operation from occurring if any of the pulse tests indicates that the fault is still present and allowing the reclosing operation to occur includes allowing the reclosing operation to occur if any of the pulse tests indicates that the fault is no longer present.

5. The method according to claim 4 wherein the first and subsequent pulse tests are performed by a triggered vacuum gap (TVG) device.

6. The method according to claim 1 wherein the first pulse test is performed at a predetermined point-on-wave time.

7. The method according to claim 1 wherein the power system is a high-voltage transmission power system.

8. The method according to claim 1 wherein the reclosing operation is performed by the switch.

9. A method for maintaining electrical stability of a high-voltage transmission power system in response to a fault, the method comprising:
detecting the fault;
opening a switch to clear the fault;
performing a first pulse test for a predetermined duration of time using a triggered vacuum gap (TVG) device to determine if the fault is still present;
performing subsequent pulse tests by the TVG device for the predetermined duration of time if the first pulse test is inclusive about the persistence of the fault;
preventing a reclosing operation by the switch from occurring if the pulse tests indicate that the fault is still present; and
allowing the reclosing operation to occur by the switch if the pulse tests indicate that the fault is no longer present.

10. The method according to claim 9 wherein the predetermined duration of time is ≤0.5 cycles.

11. The method according to claim 9 wherein the first pulse test is performed at a predetermined point-on-wave time.

12. A system for maintaining electrical stability of a power network in response to a fault, the system comprising:
sensors coupled to the power network and to a controller couple to the sensors, the sensors and controller operable to detect the fault;
an actuator coupled to a switch, the actuator being operable in the presence of a fault to open the switch to clear the fault;
a first pulse tester coupled to the power network, the first pulse tester being operable to perform a pulse test of the power network for a predetermined duration of time to determine if the fault is still present;
the actuator being configured to prevent a reclosing of the switch where the first pulse test indicates that the fault is still present; and
the actuator being further configured to provide the reclosing operation where the first pulse test indicates that the fault is not present.

13. The system according to claim 12 wherein the pulse tester comprises a triggered vacuum gap (TVG) device.

14. The system according to claim 12 wherein the predetermined duration of time is ≤0.5 cycles.

15. The system according to claim 12 the pulse tester being configured to perform subsequent pulse tests if the first pulse test indicates the fault being present, wherein the actuator is further configured to prevent a reclosing of the switch where the subsequent pulse test indicates that the fault is still present; and the actuator being further configured to provide the reclosing operation where the subsequent pulse test indicates that the fault is not present.

16. The system according to claim 15 wherein the pulse tester comprises a triggered vacuum gap (TVG) device.

17. The system according to claim 15 wherein the predetermined duration of time is ≤0.5 cycles.

18. The system according to claim 12 wherein the pulse tester is configured to perform the first pulse test at a predetermined point-on-wave time.

19. The system according to claim 12 wherein the actuator operates the switch to perform the reclosing operation.

20. The system according to claim 12 wherein the power network is a high-voltage transmission power network.
